(19) United States
(12) Patent Application Publication
(10) Pub. No.: US 2014/0291797 A1
(43) Pub. Date: Oct. 2, 2014

(54) Semiconductor Device

(71) Applicant: Sanken Electric Co., LTD., Niiza-shi (JP)

(72) Inventor: Yasuhiro Okabe, Niiza-shi (JP)

(73) Assignee: SANKEN ELECTRIC CO., LTD., Niiza-shi (JP)

(21) Appl. No.: 14/219,597

(22) Filed: Mar. 19, 2014

(30) Foreign Application Priority Data
Mar. 28, 2013 (JP) 2013-068858

(51) Int. Cl. H01L 23/495

(52) U.S. Cl. CPC H01L 23/49568
USPC 257/467

(57) ABSTRACT

A semiconductor device of this disclosure includes: a circuit element mounted on a main face of a lead frame; an inductor mounted on a back face of the lead frame; and a resin body sealing the circuit element and the inductor; wherein the circuit element includes a thermo-sensitive element and has an overheating protection function of the inductor.

### CROSS-REFERENCE TO RELATED APPLICATION

This application claims priority from Japanese Patent Application No. 2013-068858 filed on Mar. 28, 2013, the entire subject matter of which is incorporated herein by reference.

### TECHNICAL FIELD

This disclosure relates to an overheating protection of a semiconductor device in a DC-DC converter including an inductor.

### BACKGROUND

There is a semiconductor device including a DC-DC converter as a power converter for converting a power supply voltage to a predetermined operating voltage. In such a semiconductor device, a SON-type (Small Outline Non-leaded type) semiconductor device with a small size and a low profile has been generally known in which an inductor (coil), IC and capacitor are mounted on a main face of a frame. (See JP-A-2007-173712)

### SUMMARY

In the SON-type semiconductor device, components are mounted on one face of a substrate and therefore it is possible to achieve a low profile. However, it is necessary to increase the mounting area and therefore the planar dimension is increased. Further, since a distance between a heat-generating part and a thermo-sensitive element is widened due to the mounting of components on the plane, there are problems in a delay of a detection time and a detection accuracy of the temperature abnormality.

This disclosure has been made in consideration of the above problems and then provide an high-accuracy overheating protection of a semiconductor device which has a small planar dimension, while suppressing an increase in the thickness dimension.

A semiconductor device of this disclosure includes: a circuit element mounted on a main face of a lead frame; an inductor mounted on a back face of the lead frame; and a resin body sealing the circuit element and the inductor; wherein the circuit element includes a thermo-sensitive element and has an overheating protection function of the inductor.

In the above-described semiconductor device, the lead frame may be configured by a plurality of split frames which are divided from each other, and the circuit element including the thermo-sensitive element and the inductor are directly mounted on the split frames.

The above-described semiconductor device may comprise a heat sink configured to radiate heat generated inside the semiconductor device to an outside of the device.

In the above-described semiconductor device, the inductor may be configured by one of a circular columnar core and an octagonal columnar core, which is made of ferromagnetic material, and the circuit element including the thermo-sensitive element may be disposed at a position opposing to an mounting position of the inductor.

In the above-described semiconductor device, a characteristic of a coil current and a temperature rise of the inductor is a quadratic curve characteristic.

According to this disclosure, it is possible to provide an overheating protection function of a semiconductor device which has a small planar dimension while suppressing an increase in the thickness dimension.

### BRIEF DESCRIPTION OF THE DRAWINGS

The foregoing and additional features and characteristics of this disclosure will become more apparent from the following detailed descriptions considered with the reference to the accompanying drawings, wherein:

FIGS. 1A to 1C respectively illustrate a front view, a side view and a rear view for explaining an internal configuration of a semiconductor device according to an illustrative embodiment of this disclosure;

FIGS. 2A and 2B respectively illustrate a front view and a side view for explaining an external configuration of the semiconductor device according to the present embodiment of this disclosure;

FIG. 3 is a characteristic diagram of a coil current and a temperature rise of an inductor according to an illustrative embodiment of this disclosure; and

FIGS. 4A and 4B are waveform diagrams illustrating a load current in a state where a dynamic peak load current is superimposed on a DC load current, in order to explain advantages of an overheating protection operation of this disclosure.

### DETAILED DESCRIPTION

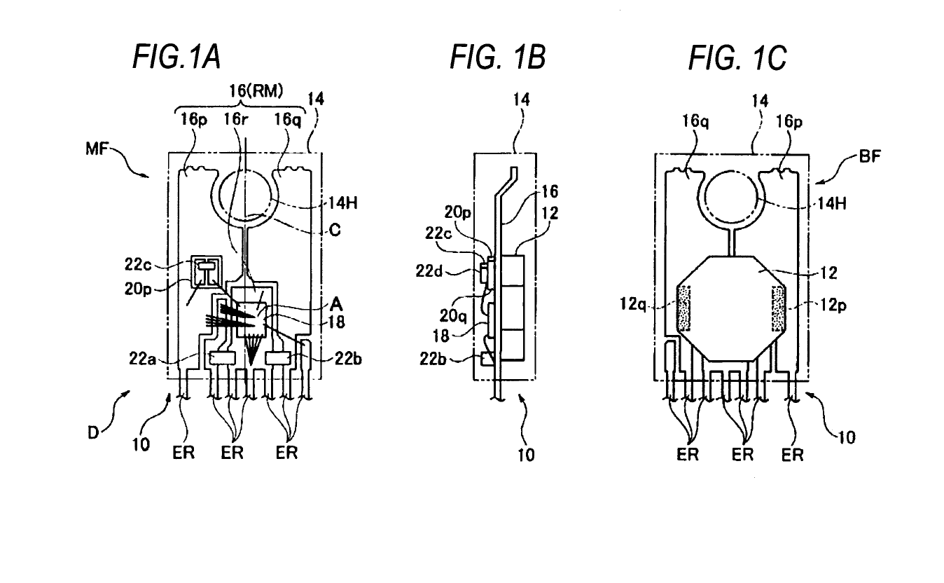

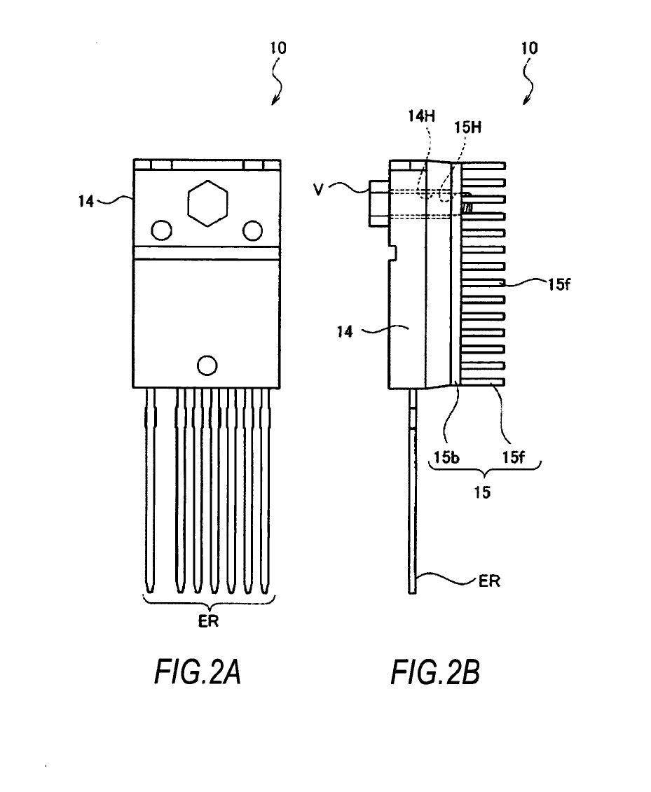

Hereinafter, an illustrative embodiment of this disclosure will be described with reference to the accompanying drawings. FIGS. 1A to 1C respectively illustrate a front view, a side view and a rear view for explaining an internal configuration of a semiconductor device according to an illustrative embodiment (hereinafter, referred to as “present embodiment”) of this disclosure. FIGS. 2A and 2B respectively illustrate a front view and a side view for explaining an external configuration of the semiconductor device according to the present embodiment of this disclosure.

A semiconductor device 10 according to the present embodiment is a SIP-type (Single In-line Package) resin-sealed semiconductor device and an inductor built-in three-terminal module (inductor built-in three-terminal regulator).

The semiconductor device 10 includes a lead frame RM, a circuit element D having a thermo-sensitive element mounted on a main face MF (front face) of the lead frame RM, an inductor (coil) 12 that is mounted on a back face BF of the lead frame RM, a resin body 14 that seals the circuit element D and the inductor 12 by resin and a heat sink 15 that is screw-fixed to an external wall of the resin body 14 in the back face BF and is adapted to radiate the heat generated inside the device to the outside of the device. Additionally, the inductor 12 is configured by one of a circular columnar core and an octagonal columnar core, which is made of ferromagnetic material.

The lead frame RM is made of metal such as copper or copper alloy. In the present embodiment, the lead frame RM is configured by three split frames 16p to 16r which are divided and are not integrated to each other. In other words, the split frames are electrically insulated from each other.

As shown in FIG. 1A, the split frames 16p and 16q are disposed at left and right positions and the split frame 16r is disposed at a center position, when viewing the semiconductor device 10 from the front side.

Further, in the present embodiment, an MIC (monolithic integrated circuit) 18, substrates 20p, 20q and chip capacitors 22a, 22b are mounted as the circuit element D.

Here, a thermo-sensitive element is mounted on a central portion A of the MIC 18.

The MIC 18 is mounted on the split frame 16r. The chip capacitor 22a is mounted across the split frames 16p and 16r, and the chip capacitor 22b is mounted across the split frames 16q and 16r.

The substrate 20p is disposed on the split frame 16p, and the substrate 20q is disposed on the split frame 16q. Further, the chip capacitor 22c is mounted on the substrate 20p.

As shown in FIG. 1B and FIG. 1C, electrical connection surfaces 12p and 12q are formed at both sides of the mounting face of the inductor 12. The inductor 12 is mounted on the back face BF of the lead frame RM so that the electrical connection surfaces 12p and 12q are to be surface-contact with the split frames 16p and 16q, respectively. Furthermore, the MIC18 on the main face MF and the inductor 12 on the back face BF are disposed to sandwich the lead frame RM therebetween.

Upon placing the circuit element D or the substrate 20 on the split frame 16, the substrate 20 is fixed to the split frame 16 in such a way that the substrate 20 is adhered by adhesive, and the circuit element D or the inductor 12 are fixed to the split frame 16 by applying and thermally curing silver paste or performing a soldering such as a reflow at the time of mounting.

In this way, the inductor 12 and the MIC 18 are thermally coupled to each other with sandwiching the split frame 16. Further, since the thermo-sensitive element is mounted on the central portion A of the MIC 18, the thermo-sensitive element is disposed at a position opposing to a mounting position of the inductor 12.

Accordingly, it is possible to accurately detect the temperature of the inductor 12 by the thermo-sensitive element of the MIC 18.

Further, the semiconductor device 10 includes a plurality of outer leads ER extending out from the resin body 14. The resin body 14 is formed by mold resin, etc., so as to seal the MIC 18, the substrate 20, the chip capacitor 22 and the portion of the split frame 16 other than the outer leads by resin. A through hole 14H is formed in an upper portion (the portion opposite to a side at which the outer lead ER extends out) of the resin body 14 of the semiconductor device. A screw can be inserted through the through hole 14H. The portion of the split frames 16p and 16q that is located at an upper side of the semiconductor device is in an arrangement and shape such that the portion is not exposed to the through hole 14H.

Further, the heat sink 15 is formed with a screw engagement hole 15H (female screw, see FIG. 2B). The heat sink 15 includes a plate-like radiation substrate 15b that comes into contact with an outer wall of the resin body 14 and a plurality of radiation fins 15f that is arranged to erect on the radiation substrate 15b. The heat sink 15 is manufactured in advance before manufacturing the semiconductor device 10. The material of the heat sink 15 is copper or aluminum, for example.

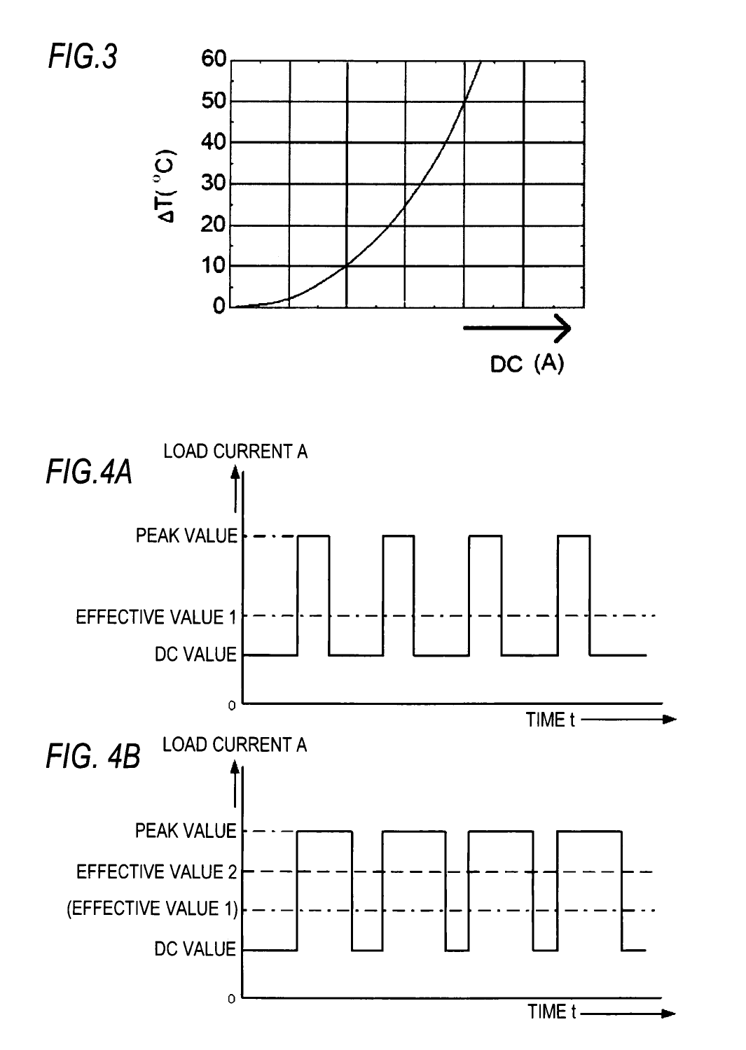

FIG. 3 is a characteristic diagram of a coil current and a temperature rise of the inductor 12. The temperature rise characteristic for the coil current of the inductor 12 plots a quadratic curve, and the temperature rise value becomes steeper as the load current flows.

In the characteristic diagram of the coil current and the temperature rise of the inductor 12, it is also possible to achieve an overload protection by setting the overheating protection value on the basis of the temperature rise value corresponding to any output current value. Specifically, in a case where the current flowing through the load refers to the current in which a dynamic peak load current is superimposed on a DC load current, the protection in a general over-current protection circuit is performed at a peak value where a dynamic peak load current is superimposed on a DC load current.

Further, although an overload state occurs when the peak load current flows continuously, as long as the load current rather than an effective value load current does not exceed an preset over-current detection value, the over-current protection is not performed in a general over-current protection circuit.

FIGS. 4A and 4B are waveform diagrams illustrating a load current in a state where a dynamic peak load current is superimposed on a DC load current. FIG. 4A shows a load current waveform in a normal operation, and FIG. 4B shows a load current waveform in an overload operation where a duty ratio of peak current is increased. Here, effective current 1 and effective current 2 shown in FIG. 4 indicate the effective current value of each load current. Here, although the effective current 2 shown in FIG. 4B has a value of 1.5 times the effective current 1 shown in FIG. 4A, a protection function is not operated because, in a general over-current protection circuit, the peak value itself of the peak load current does not exceed the prescribed value.

On the contrary, in the present embodiment, since the temperature rise value of the inductor 12 is set as an overheating protection value, it is possible to perform a protection function by rapidly detecting the temperature rise value in an overload state as shown in FIG. 4B.

In other words, it is possible to protect the DC-DC converter in both viewpoints of overheating protection and over-current protection by setting, as a rated current value, the effective current value of the load current where a dynamic peak load current is superimposed on a DC current and then setting an overheating protection value on the basis of the temperature rise value in the current value having a margin for the rated current value.

As described above, in the present embodiment, the circuit element D is mounted on the main face MF of the split frames 16p to 16r forming the lead frame RM and the inductor 12 is mounted on the back face BF opposing to the main face MF of the split frames 16p to 16r, so that a mountable space can be effectively used. Accordingly, it is possible to significantly reduce the area of the lead frame RM (split frames 16p to 16r), as compared to a case where the circuit element D and the inductor 12 are mounted only on the main face MF. Therefore, the semiconductor device 10 can have a small planar dimension while suppressing an increase in the thickness dimension (height dimension).

In addition, the semiconductor device 10 has a strong structure that is resistant to the mechanical stress such as screw fastening by mounting the MIC 18 on the main face MF and mounting the inductor 12 on the back face BF.

Further, the lead frame RM is configured by a plurality of (three) split frames 16 that are divided from each other. Accordingly, the split frames are insulated from each other and therefore the circuit elements D (the MIC 18, the substrate 20p and the chip capacitors 22a, 22b) and the inductor 12 can be directly mounted on the split frames 16. In this way, the power supply amount of the inductor 12 can be increased, as compared to a prior art. As a result, it is possible to use the inductor 12 having a capacity larger than before. Further, since the heat generated from the circuit element D or the inductor 12 can be directly transmitted to the metallic split frames 16, the semiconductor device 10 can have an excellent heat radiation characteristic. Further, since the inductor 12 and the MIC 18 are thermally coupled to each other with sandwiching the split frames 16, and the thermo-sensitive element is mounted at a position opposing to the mounting face of the inductor 12, it is possible to accurately detect the temperature of the inductor 12 by the thermo-sensitive element of the MIC.

Further, since the temperature rise value of the inductor 12 is set as the overheating protection value, it is possible to perform a protection function by rapidly detecting the temperature rise value in an overload state as shown in FIG. 4B.

Furthermore, the heat sink 15 including the radiation fins 15f is provided on the outer wall of the resin body 14 in the back face BF of the lead frame RM. As a result, the heat radiation characteristic of the semiconductor device 10 to the outside of the device is further improved, and the semiconductor device 10 can be operated with higher power without disturbing the overheating protection function.

In the above description, a case where the lead frame RM is configured by the split frames 16p to 16r has been described. However, a semiconductor device may be used in which the lead frame RM is configured by one continuous frame, the circuit element D is disposed on the front face of the lead frame and the inductor 12 is disposed on the back face BF thereof. In this case, it is preferable in the viewpoints of short-circuit prevention and overheating protection that the lead frame RM is placed on an insulative substrate, the lead frame RM and the back face BF of the substrate are insulated from each other and the inductor 12 is disposed on the back face of the substrate in which the lead frame RM is not provided.

Further, although the MIC 18, the substrate 20 and the chip capacitor 22 are employed as an example of the circuit element D in the present embodiment, a configuration other than these elements (for example, any element that generates a large amount of heat) may be included.

Further, upon forming the resin body 14, the heat sink 15 may be placed thereon and the portion on the contact surface side (resin body side) of the radiation substrate 15b may be sealed together by resin. In this way, the heat from a resin-sealed heat-generating source such as the inductor 12 is effectively transmitted to the radiation substrate 15b and therefore the heat can be radiated with high efficiency from the radiation fins 15f. Further, the heat sink 15 may be provided on the main face MF or on both of the main face MF and the back face BF.

Further, it is preferable that the thickness on the main face MF side of the resin body 14 is equal to or less than 1.7 times the thickness on the back face BF side of the resin body 14. As a result, it is easy to suppress the thermal stress generated in the resin body 14.

Although the illustrative embodiment of this disclosure has been described in the above, the illustrative embodiment is merely an example for embodying the technical spirit of this disclosure but does not specifically limit the material, shape, structure, arrangement and the like of the elements to those described above. This disclosure can be applied with various modifications without departing from the gist. Further, it should be noted that the drawings are schematic, and dimensional ratio or the like is different from the actual ratio. Accordingly, specific dimensional ratio or the like will be determined by reference to the above description. In addition, the portions having different dimensional relationship or ratio will be included among the drawings.

As described above, in the semiconductor device according to this disclosure, the inductor is mounted on the back face of the lead frame and therefore a mountable space can be effectively used. Further, since the semiconductor device has an overheating protection function, the semiconductor device can be properly used as a small semiconductor device.

What is claimed is:

1. A semiconductor device comprising:
a circuit element mounted on a main face of a lead frame;
an inductor mounted on a back face of the lead frame; and
a resin body sealing the circuit element and the inductor;
wherein the circuit element includes a thermo-sensitive element and has an overheating protection function of the inductor.

2. The semiconductor device according to claim 1,
wherein the lead frame is configured by a plurality of split frames which are divided to be separated from each other; and
wherein the circuit element including the thermo-sensitive element and the inductor are directly mounted on the split frames.

3. The semiconductor device according to claim 1, further comprising
a heat sink configured to radiate heat generated inside the semiconductor device to an outside of the device.

4. The semiconductor device according to claim 1,
wherein the inductor is configured by one of a circular columnar core and an octagonal columnar core, which is made of ferromagnetic material, and
wherein the circuit element including the thermo-sensitive element is disposed at a position opposing to an mounting position of the inductor.

5. The semiconductor device according to claim 1,
wherein a characteristic of a coil current and a temperature rise of the inductor is a quadratic curve characteristic.
